(19) United States
(12) Patent Application Publication
(10) Pub. No.: US 2010/0019766 A1
(43) Pub. Date: Jan. 28, 2010

(54) System for Dynamically Compensating for Inhomogeneity in an MR Imaging Device Magnetic Field

(75) Inventors: Sven Zuehlsdorff, Chicago, IL (US); Peter Weale, Chicago, IL (US); Saurabh Shah, Chicago, IL (US); Andreas Greiser, Erlangen (DE)

Correspondence Address: SIEMENS CORPORATION;INTELLECTUAL PROPERTY DEPARTMENT, 170 WOOD AVENUE SOUTH, ISELIN, NJ, 08830, US

(73) Assignee: Siemens Medical Solutions USA, Inc., Malvern, PA (US)

(21) Appl. No.: 12/481,649

(22) Filed: Jun. 10, 2009

Related U.S. Application Data
(60) Provisional application No. 61/084,051, filed on Jul. 28, 2008.

(51) Int. Cl. G01R 33/44

(52) U.S. Cl. 324/314

(57) ABSTRACT

A system automatically dynamically compensates for inhomogeneity in an MR imaging device magnetic field. An MR imaging compensation system applies swept frequency magnetic field variation in determining an estimate of proton spin frequency at multiple individual locations associated with individual image elements in an anatomical volume of interest and substantially independently of tissue associated relaxation time. For the multiple individual locations, the system determines an offset frequency comprising a difference between a determined estimate of proton spin frequency associated with an individual image element location and a nominal proton spin frequency. The system derives data representing an electrical signal to be applied to magnetic field generation coils to substantially compensate for determined offset frequencies at the multiple individual locations. An MR magnetic field coil generates a magnetic field in response to applying the electrical signal to substantially compensate for magnetic field variation represented by the determined offset frequencies at the multiple individual locations.

This is a non-provisional application of provisional application Ser. No. 61/084,051 filed Jul. 28, 2008, by S. Zuehlsdorff et al.

### FIELD OF THE INVENTION

This invention concerns a system for automatically dynamically compensating for inhomogeneity and variability in an MR imaging device magnetic field resulting from patient anatomical variation and other sources by determining proton spin frequency in an anatomical volume of interest and substantially independently of relaxation time.

### BACKGROUND OF THE INVENTION

In known MR imaging systems magnetic field inhomogeneity in clinical scanners is usually optimized using static and dynamic shimming. In static shimming, after installation of an MR imaging scanner, the homogeneity of a main magnetic field is compromised due to field distortions at the installation site caused by the presence of a patient or due to vicinity of other magnetic equipment, for example. The inhomogeneity is corrected using a static hardware shim involving strategically placed shimming plates within the bore of the scanner to improve magnetic field homogeneity. In dynamic shimming, insertion of any object or person into the magnet bore further distorts the local magnetic field due to susceptibility discontinuities at tissue interfaces. In particular, in a cardiac imaging study, numerous tissue interfaces, such as lung/myocardium, lung/liver interfaces, often cause severe inhomogeneities over a region of interest (ROI). This is corrected with a dynamic shim comprising magnetic field gradients of higher order that are generated to compensate for inhomogeneities during measurement. This is done by first measuring the magnetic field variations over the ROI and calculating the corresponding field gradients needed to counter-balance and subsequently homogenize the field.

In order to perform dynamic shimming, a dedicated MRI pulse sequence is used to estimate the main magnetic field variations. Typically, a multi- echo sequence, such as a DESS (double echo steady state) is applied in a three dimensional fashion. However, this approach is susceptible to motion (such as cardiac or respiratory motion) and blood flow. The accumulation of phase between the two echoes is proportional to the main magnetic field at this location and is used for magnetic field estimation. Known systems lack accuracy and are susceptible to disturbances. A system according to invention principles addresses these deficiencies and related problems.

### SUMMARY OF THE INVENTION

A system involves shimming of a main magnetic field of a magnetic resonance imaging (MRI) system independently of tissue specific parameters such as relaxation times or density and is applicable to any body region. A system automatically dynamically compensates for inhomogeneity and variability in an MR imaging device magnetic field resulting from patient anatomical variation and other sources. The system comprises an MR imaging compensation system for, applying swept frequency magnetic field variation in determining an estimate of proton spin frequency at multiple individual locations associated with individual image elements in an anatomical volume of interest and substantially independently of tissue associated relaxation time. For the multiple individual locations, the MR imaging compensation system determines an offset frequency comprising a difference between a determined estimate of proton spin frequency associated with an individual image element location and a nominal proton spin frequency. The MR imaging compensation system derives data representing an electrical signal to be applied to magnetic field generation coils to substantially compensate for determined offset frequencies at the multiple individual locations. An MR magnetic field coil generates a magnetic field in response to applying the electrical signal to substantially compensate for magnetic field variation represented by the determined offset frequencies at the multiple individual locations.

### BRIEF DESCRIPTION OF THE DRAWING

FIG. 1 shows a system for automatically dynamically compensating for inhomogeneity and variability in an MR imaging device magnetic field resulting from patient anatomical variation and other sources, according to invention principles.

FIG. 2 shows a spectral response function of a Balanced SSFP imaging pulse sequence, according to invention principles.

FIG. 3 shows MR images derived using a Balanced SSFP imaging pulse sequence and using low and high flip angles respectively, according to invention principles.

FIG. 4 illustrates spectral off-resonant frequencies resulting from magnetic field inhomogeneity for different types of tissue and blood derived using a low flip angle and a Balanced SSFP imaging pulse sequence, according to invention principles.

FIG. 5 illustrates simulation of an off-resonant spectral response frequency resulting from magnetic field inhomogeneity derived using a low flip angle and a Balanced SSFP imaging pulse sequence, according to invention principles.

FIG. 6 shows a sequence of images acquired by applying swept frequency magnetic field variation in MR imaging, according to invention principles.

FIG. 7 shows a magnetic field inhomogeneity map derived from resonant peak image data representing the images of FIG. 6, according to invention principles.

FIG. 8 illustrates banding effects resulting from magnetic field inhomogeneity and simulated using a Balanced SSFP imaging pulse sequence and low and high flip angles, according to invention principles.

FIG. 9 illustrates banding effects in an MR image resulting from magnetic field inhomogeneity, according to invention principles.

FIG. 10 illustrates calculation of frequency shift from a resonant frequency peak shift resulting from magnetic field inhomogeneity, according to invention principles.

FIGS. 11A and 11B shows a resonant peak finding executable procedure, according to invention principles.

FIGS. 12 and 13 illustrate Balanced SSFP image data acquisition, according to invention principles.

FIG. 14 illustrates Balanced SSFP image data acquisition spectral response characteristics, according to invention principles.

FIG. 15 illustrates resonant spectral frequency response banding effect movement in relation to a ROI in an MR image resulting from magnetic field center frequency offset change, according to invention principles.

FIG. 16, 17 and 18 illustrate acquired individual pixel Balanced SSFP spectral response characteristics, according to invention principles.

FIG. 19 shows a flowchart of process performed by a system for automatically dynamically compensating for inhomogeneity and variability in an MR imaging device magnetic field resulting from patient anatomical variation and other sources, according to invention principles.

### DETAILED DESCRIPTION OF THE INVENTION

An MR imaging system according to invention principles advantageously provides accurate shimming of a main magnetic field for use in a range of clinical applications in MRI such as Balanced SSFP (balanced Steady State Free Precession, including known company proprietary TrueFISP (true fast imaging with steady precession) and FIESTA (fast imaging employing steady state acquisition) sequences, for example) for imaging or spectroscopy. Balanced SSFP is a coherent technique that uses a balanced magnetic field gradient waveform. The image contrast with Balanced SSFP predominantly depends on TR (Repetition Time—the amount of time that exists between successive pulse sequences applied to the same slice) as well as relaxation times and flip angle. However, the qualitative shape of the response function is largely independent of tissue specific relaxation times. The speed and relative motion insensitivity of acquisition help to make the technique reliable even in patients who have difficulty with holding their breath.

The system employs a spectral response function of a Balanced SSFP sequence (or in another embodiment a different sequence) to estimate a main magnetic field. The quantitative nature of a Balanced SSFP spectral response function is independent of tissue specific relaxation parameters and the capability of ultra fast 2D multi slice acquisition schemes makes this technique applicable to any body region, including the heart and high-flow regions. Although the invention is discussed herein in the context of a Balanced SSFP compatible imaging process, this is exemplary only. A wide variety of imaging processes and sequences may be used that provides a frequency response function with detectable features usable for magnetic field inhomogeneity compensation according to invention principles.

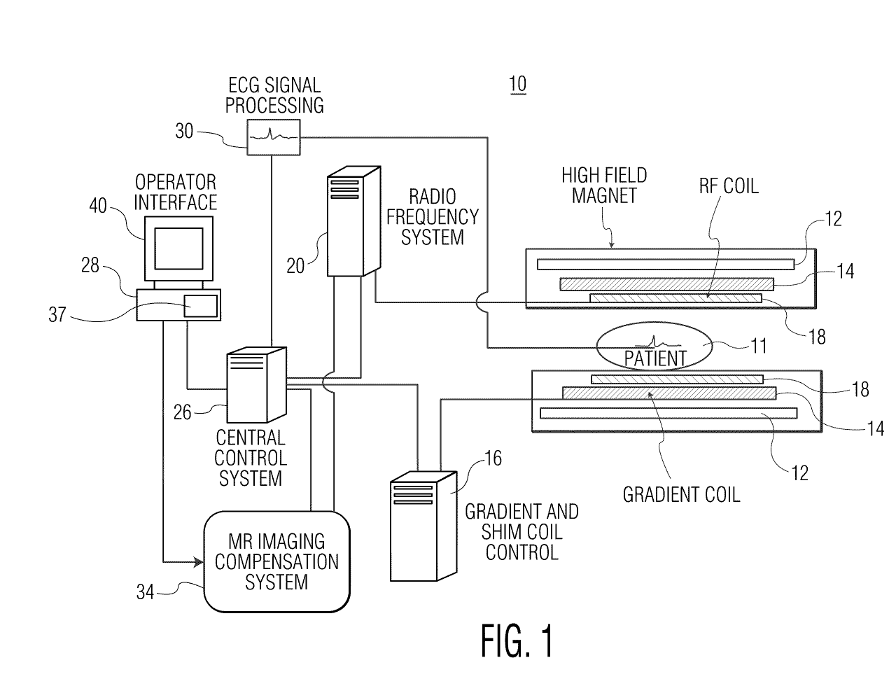

FIG. 1 shows system 10 for automatically dynamically compensating for inhomogeneity and variability in an MR imaging device magnetic field resulting from patient anatomical variation and other sources. In system 10, magnet 12 creates a static base magnetic field in the body of patient 11 to be imaged and positioned on a table. Within the magnet system are gradient coils 14 for producing position dependent magnetic field gradients superimposed on the static magnetic field. Gradient coils 14, in response to gradient signals supplied thereto by a gradient and shimming and pulse sequence control module 16, produce position dependent and shimmed magnetic field gradients in three orthogonal directions and generates pulse sequences including a Balanced SSFP compatible imaging pulse sequence. The shimmed gradients compensate for inhomogeneity and variability in an MR imaging device magnetic field resulting from patient anatomical variation and other sources and are generated in response to electrical signals provided by MR imaging magnetic field compensation system 34. The magnetic field gradients include a slice-selection gradient magnetic field, a phase-encoding gradient magnetic field and a readout gradient magnetic field that are applied to patient 11. Further RF (radio frequency) module 20 provides RF pulse signals to RF coil 18, which in response produces magnetic field pulses which rotate the spins of the protons in the imaged body 11 by ninety degrees or by one hundred and eighty degrees for so-called “spin echo” imaging, or by angles less than or equal to 90 degrees for so-called “gradient echo” imaging. Pulse sequence control module 16 in conjunction with RF module 20 as directed by central control unit 26, control slice-selection, phase-encoding, readout gradient magnetic fields, radio frequency transmission, and magnetic resonance signal detection, to acquire magnetic resonance signals representing planar slices of patient 11.

In response to applied RF pulse signals, the RF coil 18 receives MR signals, i.e., signals from the excited protons within the body as they return to an equilibrium position established by the static and gradient magnetic fields. The MR signals are detected and processed by a detector within RF module 20 to provide image representative data to an image data processor in central control unit 26. ECG synchronization signal generator 30 provides ECG signals used for pulse sequence and imaging synchronization. MR imaging compensation system 34 applies swept frequency magnetic field variation in determining an estimate of proton spin frequency at multiple individual locations associated with individual image elements in an anatomical volume of interest and substantially independently of tissue associated relaxation time. For the multiple individual locations, system 34 determines an offset frequency comprising a difference between a determined estimate of proton spin frequency associated with an individual image element location and a nominal proton spin frequency. System 34 derives data representing an electrical signal to be applied to magnetic field generation coils 14 to substantially compensate for determined offset frequencies at the multiple individual locations. MR magnetic field coils 14 generate a magnetic field in response to applying the electrical signal to substantially compensate for magnetic field variation represented by the determined offset frequencies at the multiple individual locations.

Central control unit 26 uses information stored in an internal database so as to process the detected MR signals in a coordinated manner to generate high quality images of a selected slice (or slices) of the body and adjusts other parameters of system 10. The stored information comprises predetermined pulse sequence and magnetic field gradient and strength data as well as data indicating timing, orientation and spatial volume of gradient magnetic fields to be applied in imaging. Generated images are presented on display 40. Computer 28 includes a graphical user interface (GUI) enabling user interaction with central controller 26 and enables user modification of magnetic resonance imaging signals in substantially real time. Display processor 37 processes the magnetic resonance signals to provide image representative data for display on display 40, for example.

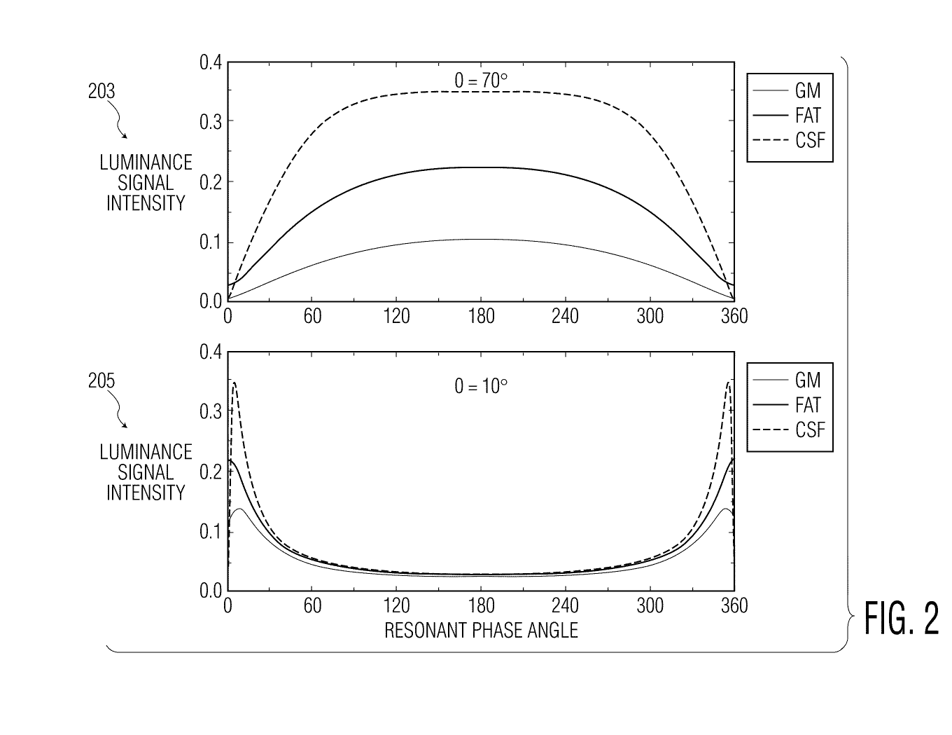

FIG. 2 shows a spectral response function of a Balanced SSFP imaging pulse sequence. Curve sets 203 and 205 show steady state spectral response functions of different anatomical matter derived using a Balanced SSFP compatible pulse sequence with high (70 degree) and low (10 degree) proton flip angles respectively. The curves show spectral response function characteristics of anatomical matter types including GM (gray matter), fat and CSF (cerebral spinal fluid). The x-axis is resonant phase angle (φ=ΔB·TR) and the y-axis is luminance signal intensity. The spectral response function of the Balanced SSFP steady state signal depends on the tissue specific relaxation times, the sequence parameters echo time (TE), repetition time (TR), flip angle θ and the phase φ that is accumulated between two consecutive excitations. This phase φ can be expressed as function of a local field inhomogeneity ΔB and φ=ΔB·TR. The response is a symmetrical and periodic function exhibiting local minima (for large θ) and maxima (for small θ) as shown in curve sets 203 and 205. Curve sets 205 illustrate the advantageous use of a Balanced SSFP pulse sequence with a low flip angle in identifying resonant peak response of individual locations associated with individual image elements in an anatomical volume of interest and substantially independently of tissue associated relaxation time. System 34 (FIG. 1) determines an offset frequency comprising a difference between a determined estimate of proton spin frequency associated with an individual image element location and a nominal proton spin frequency.

MR imaging compensation system 34 applies swept frequency magnetic field variation in determining an estimate of proton spin frequency at multiple individual locations associated with individual image elements in an anatomical volume of interest. System 34 linearly shifts an MR magnetic field center frequency in acquisition of a series of images using a Balanced SSFP compatible pulse sequence. This is analogous to tuning an MR image scanner frequency to best match resonant frequencies of protons within a volume of interest. The swept frequency magnetic field variation may also be performed in a multi slice fashion to cover a volume of interest over an appropriate frequency range.

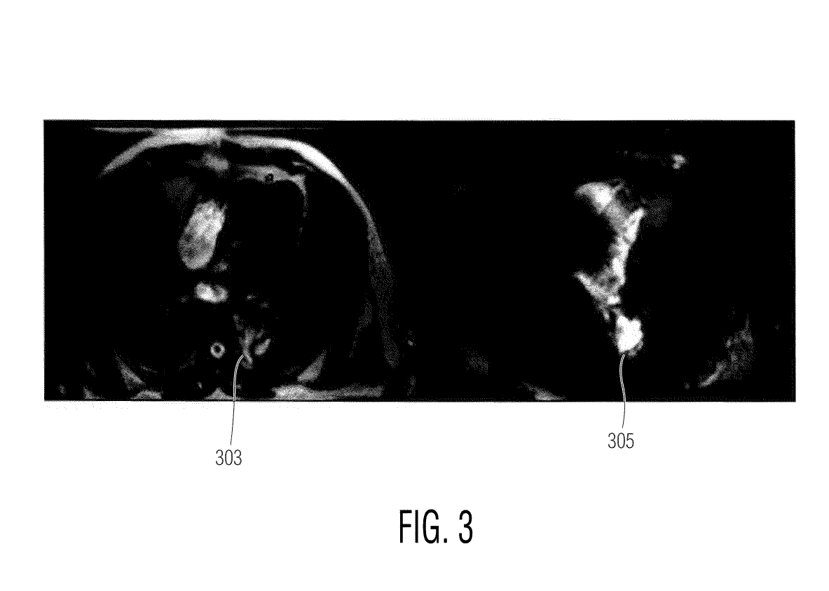

FIG. 3 shows MR images 303 and 305 derived using a Balanced SSFP imaging pulse sequence and using high and low flip angles respectively. System 10 (FIG. 1) advantageously uses images derived using swept frequency magnetic field variation to estimate not only center frequency but also distribution of a main magnetic field. MR imaging compensation System 34 (FIG. 1) applies swept frequency magnetic field variation to derive a spectral response function for individual pixels or regions of interest. For an individual pixel the spectral position of a typical minima or maxima is determined as a measure representing local field inhomogeneity. System 34 generates a map of local field inhomogeneities that is used to calculate currents for MR device magnetic field shimming coils. MR image 303 is derived using a relatively high flip angle (70 degrees) and MR image 305 is derived using a relatively low flip angle (10 degrees). Image frames 303 and 305 show local minima or maxima in associated spectral response functions, respectively and show hyper enhanced regions as a result of the spectral response function of the Balanced SSFP steady state signal.

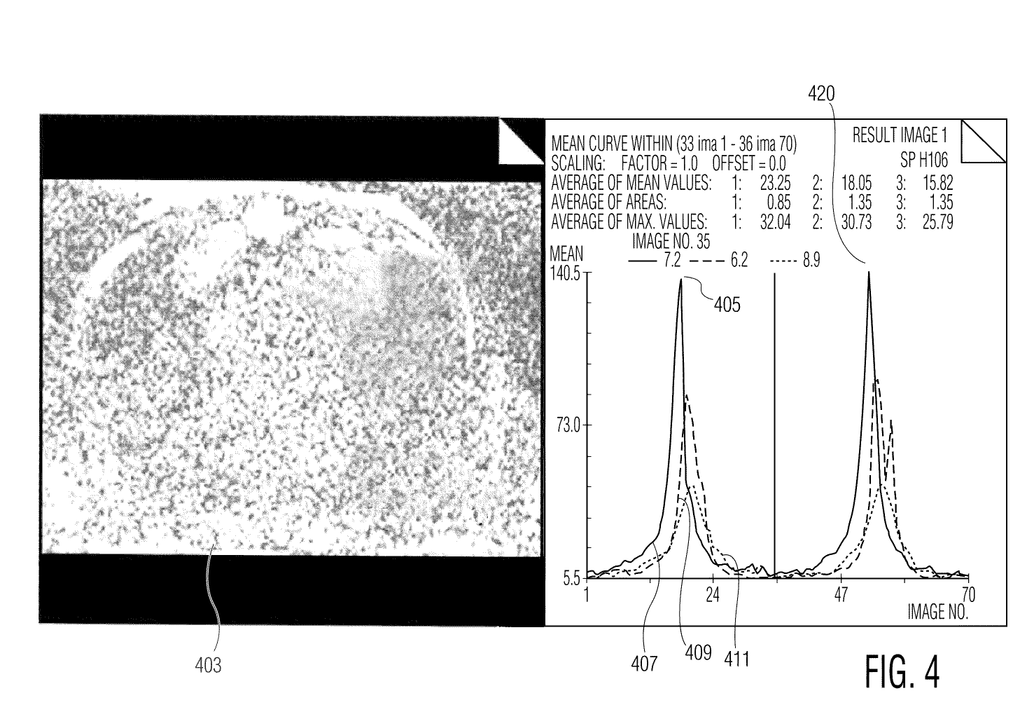

FIG. 4 illustrates spectral off-resonant frequencies resulting from magnetic field inhomogeneity for different types of tissue and blood derived using a low flip angle and a Balanced SSFP imaging pulse sequence. Curve 407 of graphs 405 shows a spectral frequency response of myocardium in a first location of a region of interest of MR image 403. The x-axis is representative of resonant phase angle (in a 0-360 degree range) and y-axis is representative of luminance signal intensity. Curve 409 of graphs 405 shows a spectral frequency response of blood in a second location of a region of interest of MR image 403. Curve 411 of graphs 405 shows a spectral frequency response of body muscle tissue in a third location of a region of interest of MR image 403. The spectral frequency response peaks of the three different types of anatomical matter are shifted due to magnetic field inhomogeneity and are measured as an offset frequency by MR imaging compensation System 34 (FIG. 1). Graphs 420 show corresponding spectral frequency response curves in a higher order resonant phase angle range (360-720 degrees).

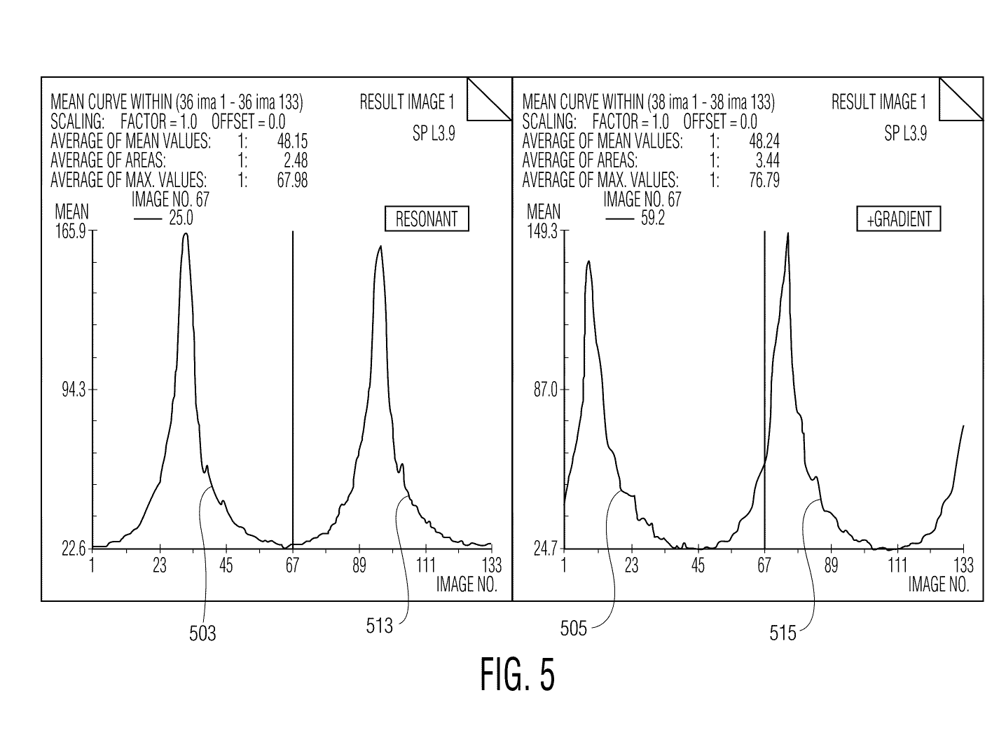

The shift in spectral frequency response of anatomical matter is demonstrated in FIG. 5 where an additional gradient is applied to simulate severely compromised magnetic field inhomogeneity. The frequency of an initially resonant condition is substantially shifted and measured by MR imaging compensation system 34. FIG. 5 illustrates simulation of an off-resonant spectral response frequency resulting from magnetic field inhomogeneity derived using a low flip angle and a Balanced SSFP imaging pulse sequence. An additional magnetic field gradient is applied in MR imaging unit coils simulating effect of inhomogeneity and shifting resonant spectral frequency response of curve 503 to produce a frequency offset resonant spectral frequency response curve 505. MR imaging compensation system 34 (FIG. 1) determines an offset frequency comprising a difference between frequencies of resonant peaks of curves 503 and 505 representing proton spin frequencies and nominal proton spin frequency associated with an individual image element location. Frequency response curves 513 and 515 show spectral frequency response curves (corresponding to curves 503 and 505) in a higher order resonant phase angle range.

The spectral response function is dependent on imaging as well as tissue specific parameters. However, the location in frequency space of a local minima and maxima does not depend on these parameters. System 10 employs a process (e.g., in one embodiment involving an algorithm) that allows finding frequencies of local minima and maxima associated with individual pixels. System 10 optimizes magnetic field inhomogeneity compensation for different applications by selection of imaging protocol parameters including frequency span and number of data points (image frames) acquired. Due to the periodic nature of the spectral response function, system 34 determines offset frequencies modulo 1/TR and applies a frequency unwrapping method for high field inhomogeneities.

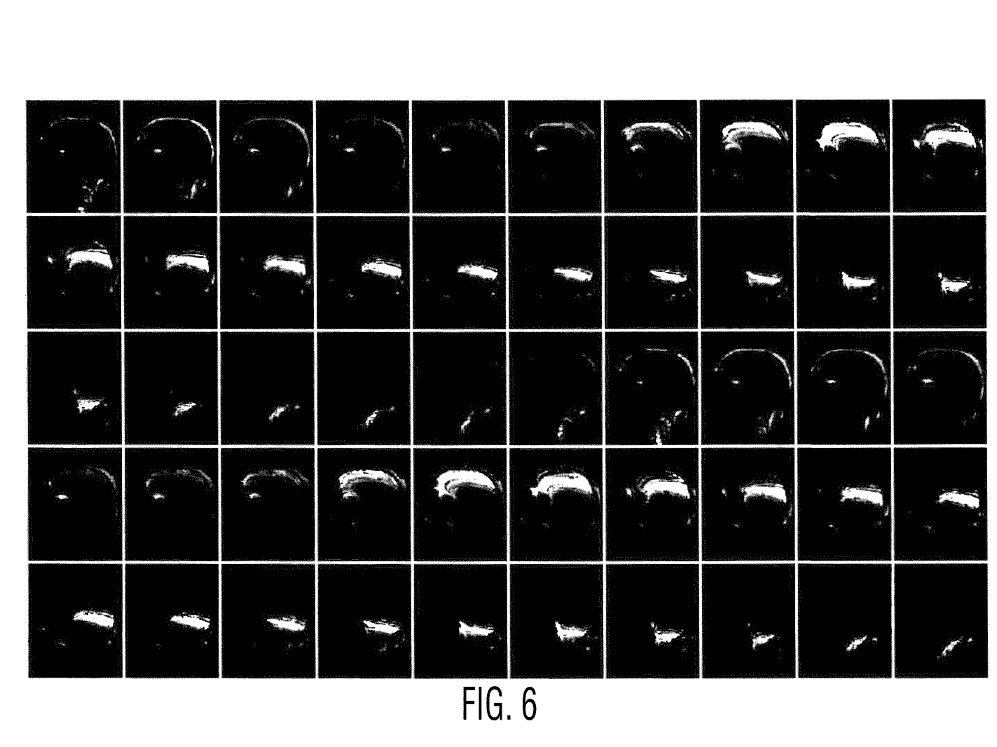

FIG. 6 shows a sequence of images of a ROI in a patient head acquired by System 34 (FIG. 1) by applying swept frequency magnetic field variation in MR imaging. The sequence of images is obtained by system 34 incrementally linearly shifting an MR magnetic field center frequency in acquisition of a series of images and by use of a Balanced SSFP compatible pulse sequence using a low flip angle. The shift in image luminance intensity peak resulting from shifting of the MR magnetic field center frequency is indicated by the moving bright area as the images progress illustrating a pattern of banding artifacts moving according to spectral response function. Depending on MR imaging protocol parameters, the bandings are signal voids or elevated signals and are shifted depending on the center frequency of the image frame.

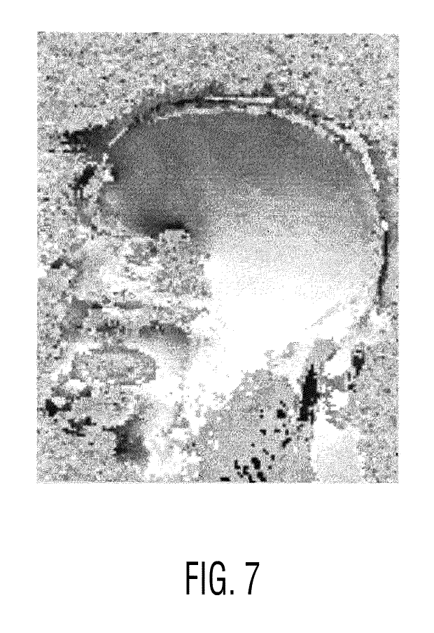

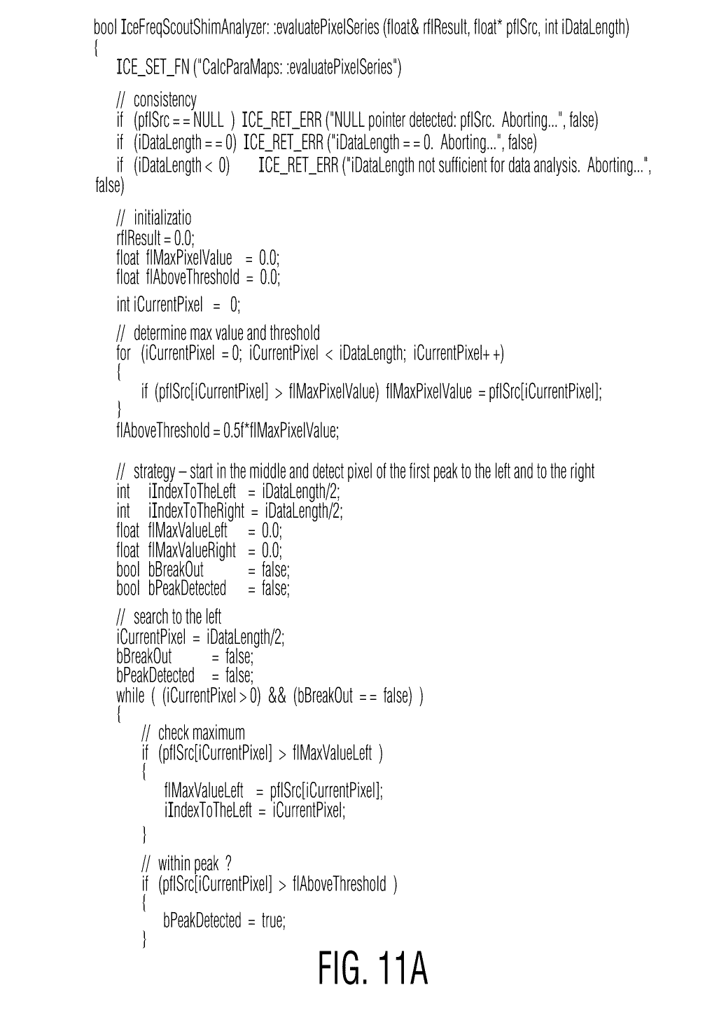

FIG. 7 shows a magnetic field inhomogeneity map derived from resonant peak data in image data comprising the images of FIG. 6. MR imaging compensation System 34 (FIG. 1) processes the image data comprising the images of FIG. 6 by identifying luminance intensity peak values of individual pixels of the sequence of images. System 34 selects a maximum luminance peak value for an individual pixel from luminance peak values of the individual pixel occurring in the individual images comprising the sequence of FIG. 6. System 34 selects a maximum luminance peak value for an individual pixel from luminance peak values of the individual pixel occurring in the individual images using a resonant peak detection executable procedure such as the procedure shown in FIGS. 11A and 11 B. The executable procedure also calculates the frequency shift of the response function for each pixel and generates data comprising the FIG. 7 magnetic field inhomogeneity representative image. In other embodiments a procedure is used that detects desired specific features of a particular response function.

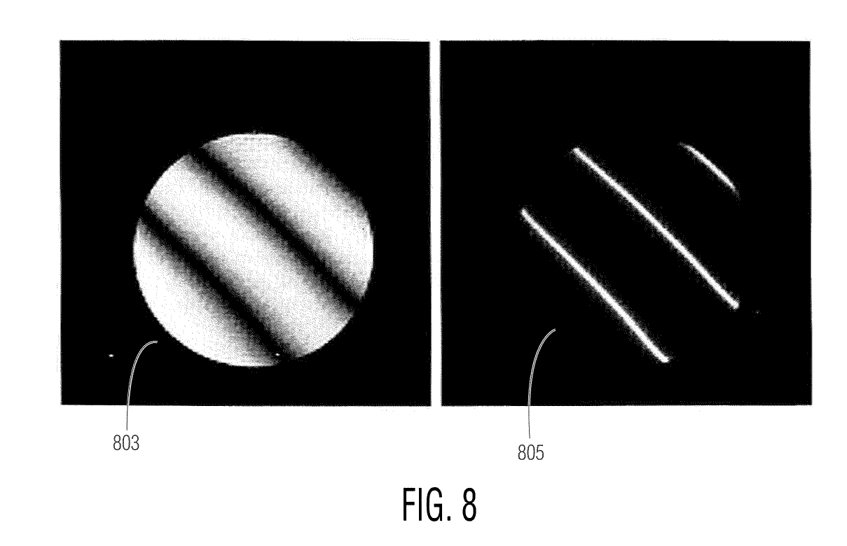

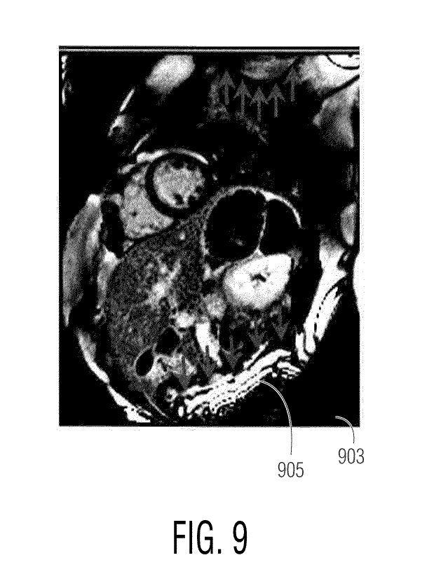

FIG. 8 illustrates banding effects resulting from magnetic field inhomogeneity simulated using a Balanced SSFP imaging pulse sequence and low and high flip angles. Depending on the flip angle θ, the image appearance of Balanced SSFP images shows regions with low signals or elevated signal values, known as banding artifacts. For illustration, the phantom images of FIG. 8 are acquired in an inhomogeneous field. Image 803 shows a phantom in an inhomogeneous field for a high flip angle θ and image 805 shows a phantom in an inhomogeneous field for a low flip angle θ. The contrast of the banding artifacts inverts as flip angle is changed from high to low. Further, acquired in vivo images usually show severe banding artifacts in regions where an MR scanner magnetic field is collapsing (outside a field-of-view) compromising field homogeneity, but also in regions where tissue-air-lung interfaces cause field inhomogeneities. FIG. 9 illustrates banding effects 905 resulting from magnetic field inhomogeneity on the periphery of a field-of-view in an MR image 903 acquired using a high flip angle and Balanced SSFP compatible pulse sequence, for example.

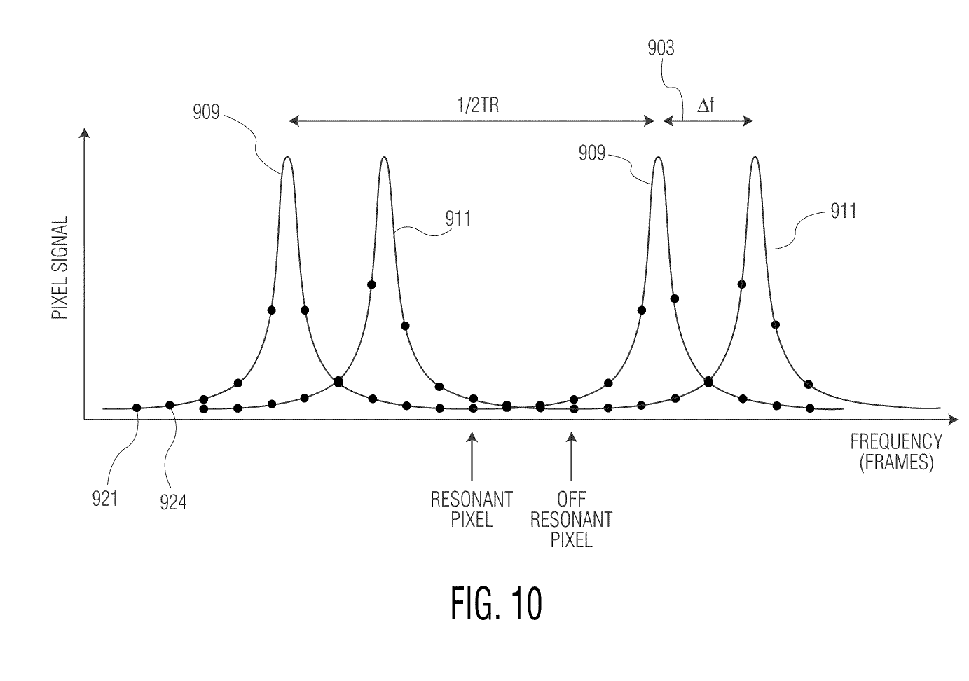

FIG. 10 illustrates calculation of frequency shift from a resonant frequency peak shift resulting from magnetic field inhomogeneity. System 34 (FIG. 1) applies swept frequency magnetic field variation in MR imaging to derive the spectral response function of FIG. 10 with resonant phase angle plotted on the x-axis and pixel luminance intensity on the y-axis. System 34 derives a spectral response function for individual pixels on a pixel-by-pixel basis. Spectral response function 909 is for a resonant pixel and spectral response function 911 is for a pixel at a location with a slightly different main magnetic field. System 34 analyzes the shift of the spectral response function to determine frequency shift 903. Dots (e.g., dots 921 and 924) indicate points measured by system 34 (TR=repetition time, Δf=off center frequency proportional to a main magnetic field).

A response function is predictable and in an on resonance condition is symmetric about a system magnetic field center frequency (approximately 64 MHz in a 1.5 T magnetic field). Alternative embodiments may use a different response function with clearly frequency dependent identifiable features. For a given repetition time (TR), the distance between either maxima (in the case of a low flip angle acquisition) or minima (in the case of the high flip angle acquisition), is determined by the reciprocal of twice the repetition time. The accuracy of depiction of the response function is adjustable by increasing or reducing the number of samples acquired over a determined frequency range. The resultant images acquired by the system are analyzed on a pixel by pixel basis to detect MR signal maxima (or minima) and to correlate signal maxima (or minima) with an offset frequency of a region in the object corresponding to a particular pixel. In the case of a pixel corresponding to a region where the magnetic field is homogenous, with a resonant frequency corresponding to the system frequency an extrema (e.g. maximum or minimum) is detected at a predicted offset from the system frequency at a frequency offset of ±(1TR). For example, with a TR period of 4 ms, the expected frequency offset for the maxima is at ±250 Hz.

In the case where a maxima (for example, the positive maximum) is detected at a frequency different from the expected value, the difference in frequency from the expected value is directly correlated with an offset of the magnetic field at this point from the nominal field strength. For example, in the case where the positive maximum point is detected at 200 Hz rather than 250 Hz the difference between the two (50 Hz) corresponds (assuming a commonly used imaging frequency of 63 MHz) to 0.79 parts per million. In the above non-resonant condition the expected negative maximum occurs at −300 Hz and detection of this second point improves accuracy in detection of the frequency offset. Further, increased accuracy in maxima detection is achieved using a curve fitting method rather than simple detection of maximal pixel values.

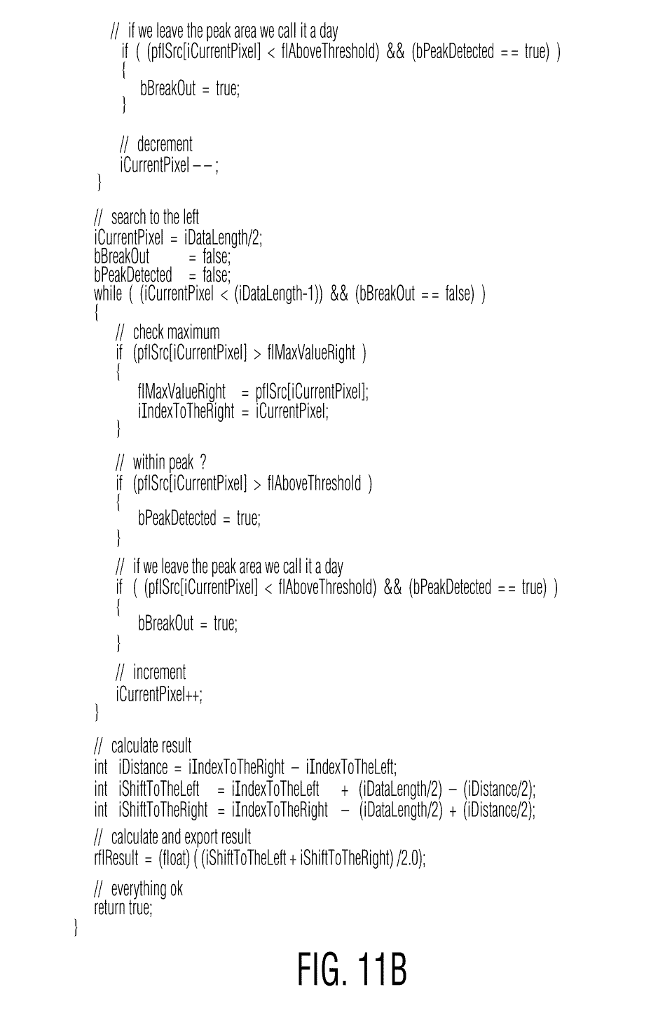

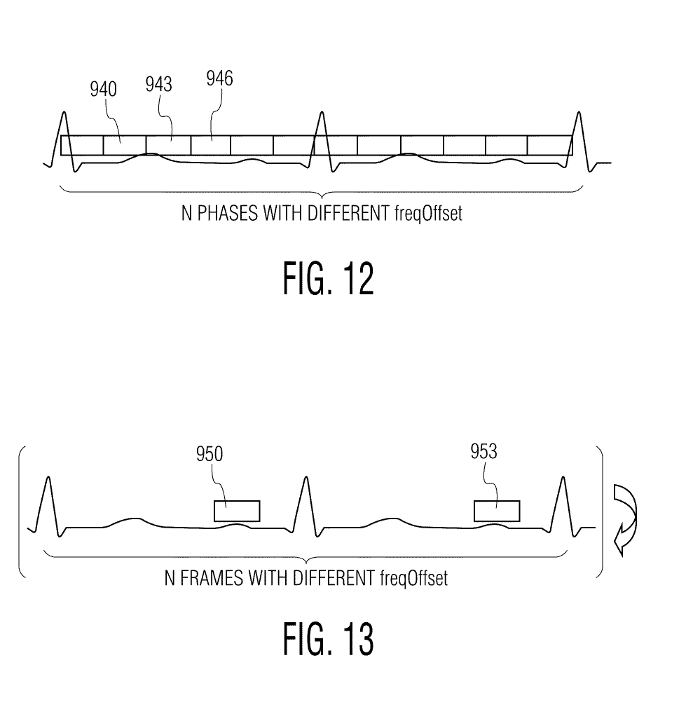

FIGS. 12 and 13 illustrate rapid image data acquisition using a Balanced SSFP compatible pulse sequence with a low flip angle. FIG. 12 indicates a sequence of data sets (including data sets 940, 943 and 946) representing multiple images of the same 2D ROI acquired by system 10 (FIG. 1) with incremental linear shift in MR magnetic field center frequency determined by System 34 (FIG. 1). System 10 (FIG. 1) successively acquires image representative data sets for a sequence of images such as those of FIG. 6 with multiple images acquired within individual heart cycles. In contrast, FIG. 13 illustrates a further embodiment in which system 10 uses a Balanced SSFP compatible pulse sequence with a low flip angle to acquire a sequence of image data sets including data sets 950 and 953 representing images of the same 2D ROI with a single data set being acquired in each heart cycle.

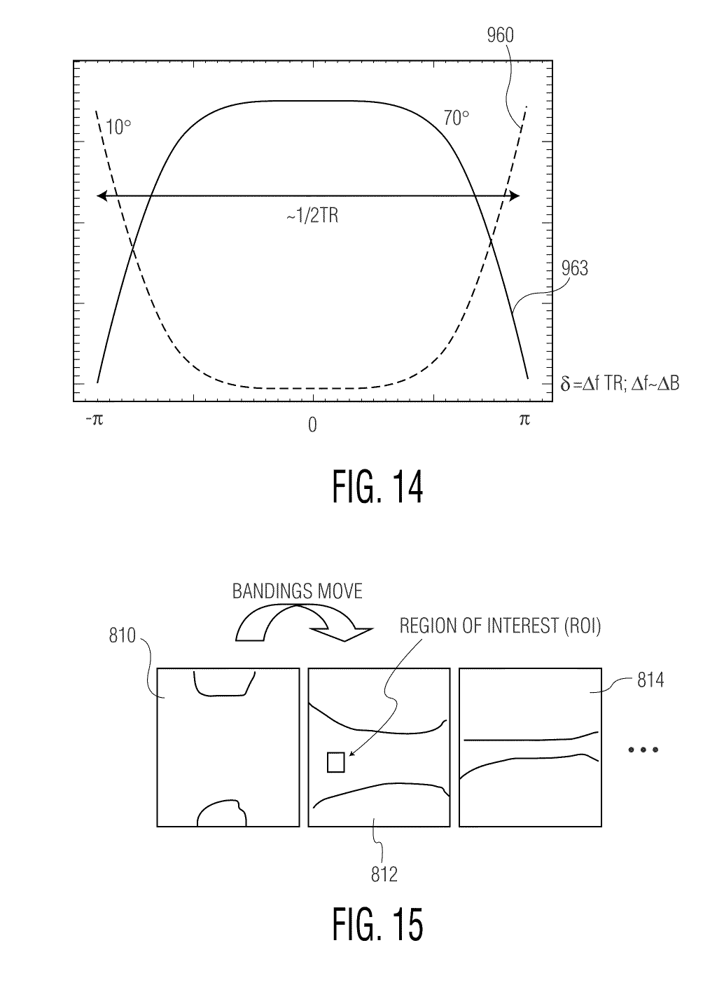

FIG. 14 illustrates Balanced SSFP image data acquisition spectral response characteristics presenting curves 960, 963 of resonant phase angle (x-axis) versus luminance intensity (y-axis) for low and high flip angle respectively. Balanced SSFP steady state magnetic field Mss for (TR<<T1, T2) is given by,

$${M}_{SS} = {M}_{0} \frac{sin α}{( {T}_{1} / {T}_{2} + 1 ) - cos α ( {T}_{1} / {T}_{2} - 1 )}$$

Where Mo=equilibrium magnetic field (T per cubic m) TR=repetition time, T1, T2=relaxation parameters and α=flip angle.

A Balanced SSFP spectral response function is given by,

$${M}_{x}^{+} = {M}_{0} ( {E}_{1} - 1 ) \frac{{E}_{2} sin α \cdot sin δ}{d}$$

$${M}_{y}^{+} = {M}_{0} ( {E}_{1} - 1 ) \frac{sin α ( 1 + {E}_{2} cos δ )}{d}$$

$${M}_{z}^{+} = {M}_{0} ( {E}_{1} - 1 ) \frac{{E}_{2} ( {E}_{2} + cos δ ) + ( 1 + {E}_{2} cos δ ) cos α}{d}$$

$$d = ( 1 - {E}_{1} cos α ) ( 1 + {E}_{2} cos δ ) - {E}_{2} ( {E}_{1} - cos α ) ( {E}_{2} + cos δ )$$

$${E}_{1} = exp ( - TR / {T}_{1} ) und {E}_{2} = exp ( - Tr / {T}_{2} )$$

Where δ=phase accumulated during TR due to field inhomogeneity, Mx, My, Mz=Magnetization in x, y, z directions.

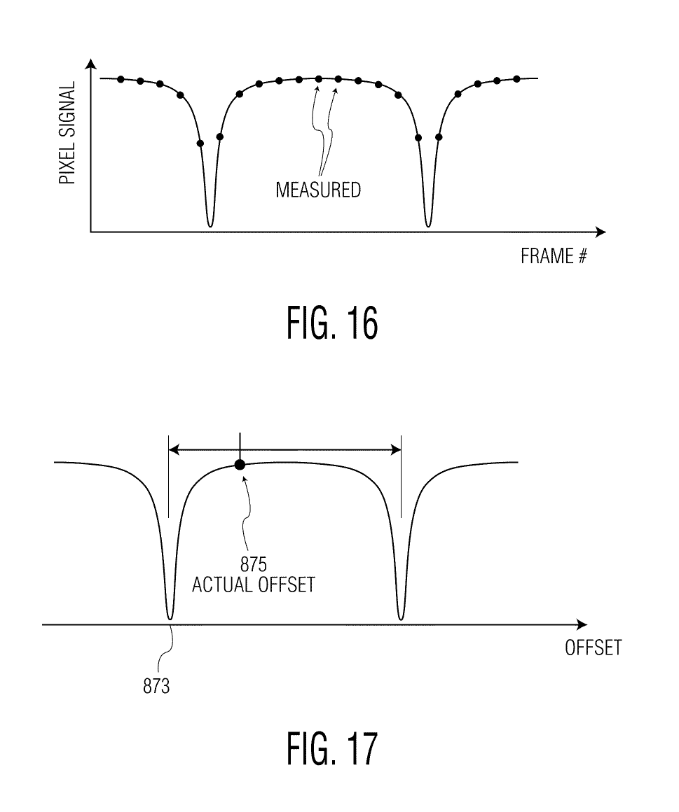

FIG. 15 illustrates resonant spectral frequency response banding effect movement in relation to a ROI in an MR image resulting from magnetic field center frequency offset change. Specifically, sequence of image frames 810, 812 and 814 of the same 2D ROI illustrates movement of inhomogeneity indicative banding with incremental linear shift in MR magnetic field center frequency (determined by system 34) used in acquisition of the three images.

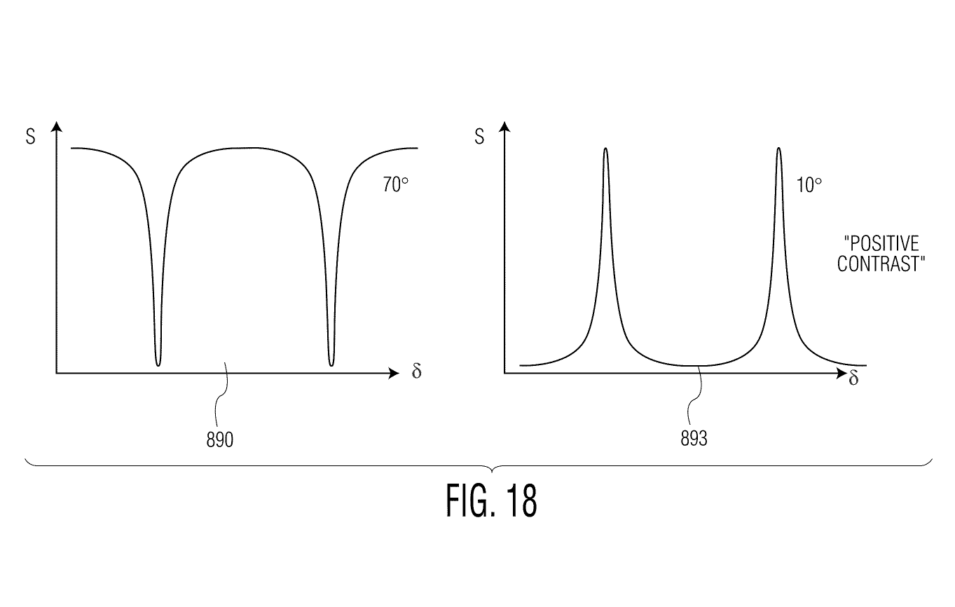

FIG. 16, 17 and 18 illustrate acquired individual pixel Balanced SSFP spectral response characteristic processing. MR imaging compensation System 34 (FIG. 1) processes spectral response characteristics of individual pixels of a ROI of a sequence of images, on a pixel-by-pixel basis. The same individual pixel is identified in the sequence of images after registration and mutual alignment of the images. In one embodiment, MR imaging compensation system 34 determines an offset frequency (modulo 1/2TR) for individual pixels by analyzing a pixel spectral response function (or inverted response function) either by fitting a curve or by performing a minimum or maximum identification. FIG. 16 illustrates fitting a curve to measured individual luminance intensity value points (y-axis) for an individual pixel of a sequence of different images identified on the x-axis. FIG. 17 shows qualitative shape of the spectral response function which is independent of a wide range of T1/T2 values. Further, the curve repeats at a 1/2TR interval and shows an offset frequency as the frequency range (as indicated on the x-axis) between the individual pixel resonant peak 873 and the nominal resonant frequency at point 875 on the curve. FIG. 18 shows spectral response curves 890 and 893 derived using a Balanced SSFP compatible pulse sequence. Curve 890 illustrates negative contrast (e.g., showing as negative luminance contrast in a banding image) and curve 893 illustrates positive contrast (e.g., positive luminance contrast in a banding image). Further, curve 890 shows pixel luminance (y-axis) versus resonant phase angle (x-axis) for a high proton spin flip angle (70 degrees). Curve 893 shows pixel luminance (y-axis) versus resonant phase angle (x-axis) for a low proton spin flip angle (10 degrees).

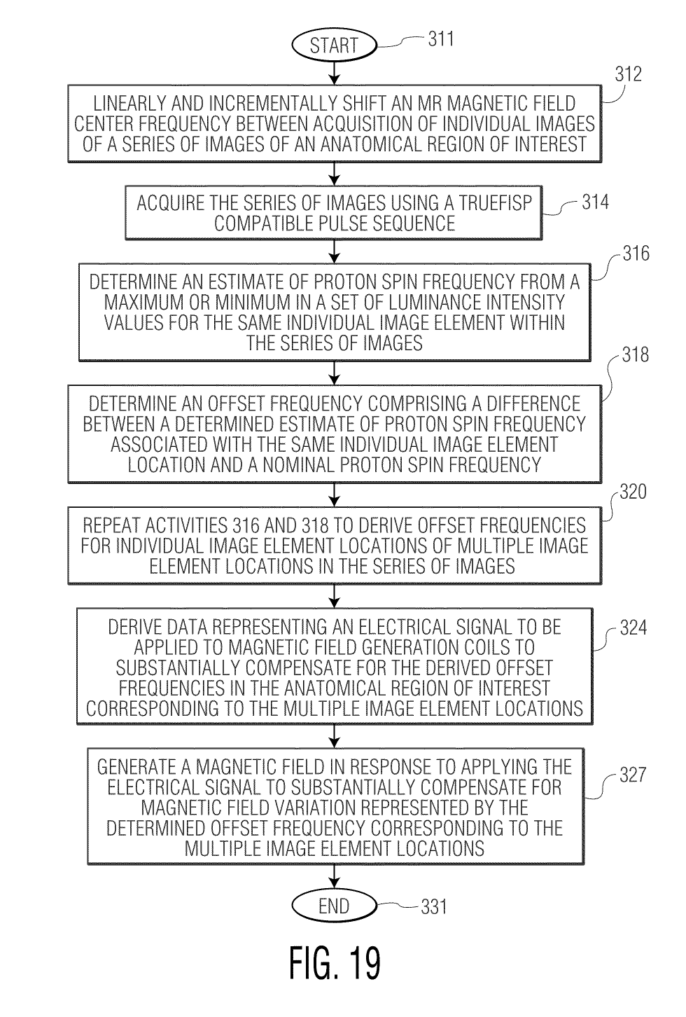

FIG. 19 shows a flowchart of process performed by a system for automatically dynamically compensating for inhomogeneity and variability in an MR imaging device magnetic field resulting from patient anatomical variation and other sources. In step 312, MR imaging compensation System 34 (FIG. 1) in conjunction with unit 16, following the start at step 311, applies swept frequency magnetic field variation in linearly and incrementally shifting an MR magnetic field center frequency between acquisition of individual images of a series of images of an anatomical region or volume of interest. In one embodiment, system 34 applies swept frequency magnetic field variation in a multi slice fashion over the volume of interest. In step 314, MR imaging system 10 acquires the series of images using a Balanced SSFP compatible process and pulse sequence. System 34 in step 316 determines an estimate of proton spin frequency from a maximum or minimum in a set of luminance intensity values for the same individual image element location within the series of images substantially independently of tissue associated relaxation time. System 34 determines an estimate of proton spin frequency from a maximum or minimum in a set of luminance intensity values comprising a spectral response for the same individual image element within the series of images by varying a center frequency of the magnetic field over a bandwidth portion in response to a swept frequency signal and swept frequency signal bandwidth range setting. System 34 determines the proton spin frequency by determining a spectral response at multiple individual locations associated with individual image elements by varying a frequency of the magnetic field over a bandwidth portion in response to a swept frequency signal.

In step 318, system 34 determines an offset frequency comprising a difference between a determined estimate of proton spin frequency associated with the same individual image element location and a nominal proton spin frequency. System 34 in step 320 repeats steps 316 and 318 to derive offset frequencies for individual image element locations of multiple image element locations in the series of images. In step 324, system 34 derives data representing an electrical signal to be applied to magnetic field generation coils to substantially compensate for the derived offset frequencies in the anatomical region of interest corresponding to the multiple image element locations by calculation of shimming currents using one of a variety of known methods. Such known methods are indicated in Optimization of Static Magnetic Field Homogeneity in the Human and Animal Brain in Vivo, by K. M. Koch et al published 2009 pages 69-96 of Progress in Nuclear Magnetic Resonance Spectroscopy 54, for example. The electrical signal comprises at least one of, (a) a current and (b) a voltage, applied to magnetic field generation coils. An individual image element comprises at least one of, (a) an individual pixel and (b) a group of individual pixels. In step 327, unit 16 and coils 18 generate a magnetic field in response to applying the electrical signal to substantially compensate for magnetic field variation represented by the determined offset frequency corresponding to the multiple individual image element locations. MR imaging compensation system 34 employs different first and second imaging parameters in compensating for magnetic field inhomogeneity of different ranges of magnitude. The process of FIG. 19 terminates at step 331.

A processor as used herein is a device for executing machine-readable instructions stored on a computer readable medium, for performing tasks and may comprise any one or combination of, hardware and firmware. A processor may also comprise memory storing machine-readable instructions executable for performing tasks. A processor acts upon information by manipulating, analyzing, modifying, converting or transmitting information for use by an executable procedure or an information device, and/or by routing the information to an output device. A processor may use or comprise the capabilities of a controller or microprocessor, for example, and is conditioned using executable instructions to perform special purpose functions not performed by a general purpose computer. A processor may be coupled (electrically and/or as comprising executable components) with any other processor enabling interaction and/or communication there-between. A user interface processor or generator is a known element comprising electronic circuitry or software or a combination of both for generating display images or portions thereof. A user interface comprises one or more display images enabling user interaction with a processor or other device.

An executable application, as used herein, comprises code or machine readable instructions for conditioning the processor to implement predetermined functions, such as those of an operating system, a context data acquisition system or other information processing system, for example, in response to user command or input. An executable procedure is a segment of code or machine readable instruction, sub-routine, or other distinct section of code or portion of an executable application for performing one or more particular processes. These processes may include receiving input data and/or parameters, performing operations on received input data and/or performing functions in response to received input parameters, and providing resulting output data and/or parameters. A user interface (UI), as used herein, comprises one or more display images, generated by a user interface processor and enabling user interaction with a processor or other device and associated data acquisition and processing functions.

The UI also includes an executable procedure or executable application. The executable procedure or executable application conditions the user interface processor to generate signals representing the UI display images. These signals are supplied to a display device which displays the image for viewing by the user. The executable procedure or executable application further receives signals from user input devices, such as a keyboard, mouse, light pen, touch screen or any other means allowing a user to provide data to a processor. The processor, under control of an executable procedure or executable application, manipulates the UI display images in response to signals received from the input devices. In this way, the user interacts with the display image using the input devices, enabling user interaction with the processor or other device. The functions and process steps herein may be performed automatically or wholly or partially in response to user command. An activity (including a step) performed automatically is performed in response to executable instruction or device operation without user direct initiation of the activity.

The system and processes of FIGS. 1-19 are not exclusive. Other systems, processes and menus may be derived in accordance with the principles of the invention to accomplish the same objectives. Although this invention has been described with reference to particular embodiments, it is to be understood that the embodiments and variations shown and described herein are for illustration purposes only. Modifications to the current design may be implemented by those skilled in the art, without departing from the scope of the invention. The MR imaging system advantageously provides accurate shimming of a main magnetic field for use in a range of clinical applications in MRI such as Balanced SSFP imaging or spectroscopy. Further, the processes and applications may, in alternative embodiments, be located on one or more (e.g., distributed) processing devices on the network of FIG. 1. Any of the functions and steps provided in FIGS. 1-19 may be implemented in hardware, software or a combination of both.

What is claimed is:

1. A system for automatically dynamically compensating for inhomogeneity and variability in an MR imaging device magnetic field resulting from patient anatomical variation and other sources, comprising:
an MR imaging compensation system for,
applying swept frequency magnetic field variation in determining an estimate of proton spin frequency at a plurality of individual locations associated with individual image elements in an anatomical volume of interest and substantially independently of tissue associated relaxation time,
for the plurality of individual locations, determining an offset frequency comprising a difference between a determined estimate of proton spin frequency associated with an individual image element location and a nominal proton spin frequency,
deriving data representing an electrical signal to be applied to magnetic field generation coils to substantially compensate for determined offset frequencies at said plurality of individual locations, and
an MR magnetic field coil for generating a magnetic field in response to applying said electrical signal to substantially compensate for magnetic field variation represented by the determined offset frequencies at said plurality of individual locations.

2. A system according to claim 1, wherein
said electrical signal comprises at least one of, (a) a current and (b) a voltage, applied to magnetic field generation coils.

3. A system according to claim 1, wherein
said MR imaging compensation system determines a proton spin frequency by determining a spectral response at said plurality of individual locations associated with individual image elements by varying a frequency of said magnetic field over a bandwidth portion in response to a swept frequency signal.

4. A system according to claim 3, wherein
said MR imaging compensation system determines a proton spin frequency from a maximum or minimum in luminance intensity representative values in said spectral response.

5. A system according to claim 3, wherein
said frequency of said magnetic field is varied over said bandwidth portion in response to a predetermined swept frequency signal bandwidth range setting.

6. A system according to claim 1, wherein
said MR imaging compensation system determines said spectral response using a Balanced SSFP (balanced Steady State Free Precession) compatible imaging process.

7. A system according to claim 1, wherein
said MR imaging compensation system employs different first and second imaging parameters in compensating for magnetic field inhomogeneity of different ranges of magnitude.

8. A system according to claim 1, wherein
said MR imaging compensation system,
linearly and incrementally shifts an MR magnetic field center frequency between acquisition of individual images of a series of images of the anatomical volume of interest,
determines an estimate of proton spin frequency from a maximum or minimum in a set of luminance intensity values for the same individual image element location within said series of images,
determines an offset frequency comprising a difference between a determined estimate of proton spin frequency associated with the same individual image element location and a nominal proton spin frequency and
derives data representing an electrical signal to be applied to magnetic field generation coils to substantially compensate for a determined offset frequency in said anatomical volume of interest corresponding to the same individual image element location.

9. A system according to claim 1, wherein
said MR imaging compensation system applies swept frequency magnetic field variation in a multi slice fashion over the volume of interest.

10. A system according to claim 1, wherein
said individual image elements comprise at least one of, (a) an individual pixel and (b) a group of individual pixels.

11. A system for automatically dynamically compensating for inhomogeneity and variability in an MR imaging device magnetic field resulting from patient anatomical variation and other sources, comprising:
an MR imaging compensation system for,
linearly and incrementally shifting an MR magnetic field center frequency between acquisition of individual images of a series of images of an anatomical region of interest,
determining an estimate of proton spin frequency from a maximum or minimum in a set of luminance intensity values for the same individual image element location within said series of images,
determining an offset frequency comprising a difference between a determined estimate of proton spin frequency associated with the same individual image element location and a nominal proton spin frequency,
deriving data representing an electrical signal to be applied to magnetic field generation coils to substantially compensate for a determined offset frequency in said anatomical region of interest corresponding to the same individual image element location, and
an MR magnetic field coil for generating a magnetic field in response to applying said electrical signal to substantially compensate for magnetic field variation represented by the determined offset frequency corresponding to the same individual image element location.

12. A system according to claim 11, wherein
an individual image element comprises at least one of, (a) an individual pixel and (b) a group of individual pixels.

13. A system according to claim 11, including
an MR imaging device for acquiring said series of images using a Balanced SSFP compatible pulse sequence.

14. A system according to claim 11, wherein
said MR imaging compensation system determines said estimate of proton spin frequency substantially independently of tissue associated relaxation time.

15. A system according to claim 11, wherein
said MR imaging compensation system,
determines an estimate of proton spin frequency for a plurality of individual image elements within said series of images,
determines an offset frequency for said plurality of individual image elements,
derives data representing an electrical signal to be applied to magnetic field generation coils to substantially compensate for determined offset frequencies in said anatomical region of interest corresponding to said plurality of individual image elements.

16. A system according to claim 11, wherein
said MR imaging compensation system determines an estimate of proton spin frequency from a maximum or minimum in a set of luminance intensity values comprising a spectral response for the same individual image element within said series of images by varying a center frequency of said magnetic field over a bandwidth portion in response to a swept frequency signal.

17. A method for automatically dynamically compensating for inhomogeneity and variability in an MR imaging device magnetic field resulting from patient anatomical variation and other sources, comprising the activities of:
(a) linearly and incrementally shifting an MR magnetic field center frequency between acquisition of individual images of a series of images of an anatomical region of interest,
(b) determining an estimate of proton spin frequency from a maximum or minimum in a set of luminance intensity values for the same individual image element location within said series of images,
(c) determining an offset frequency comprising a difference between a determined estimate of proton spin frequency associated with the same individual image element location and a nominal proton spin frequency,
(d) repeating activities b and c to derive offset frequencies for individual image element locations of a plurality of image element locations in said series of images and
(e) deriving data representing an electrical signal to be applied to magnetic field generation coils to substantially compensate for the derived offset frequencies in said anatomical region of interest corresponding to the plurality of image element locations, and
an MR magnetic field coil for generating a magnetic field in response to applying said electrical signal to substantially compensate for magnetic field variation represented by the determined offset frequency corresponding to the plurality of individual image element location.
